(19) United States
(12) Patent Application Publication
(10) Pub. No.: US 2023/0207703 A1
(43) Pub. Date: Jun. 29, 2023

(54) VERTICALLY AND HORIZONTALLY STACKED DEVICE STRUCTURES

(71) Applicant: INTERNATIONAL BUSINESS MACHINES CORPORATION, Armonk, NY (US)

(72) Inventors: Shogo Mochizuki, Mechanicville, NY (US); Juntao Li, Cohoes, NY (US); Kangguo Cheng, Schenectady, NY (US)

(21) Appl. No.: 17/563,749

(22) Filed: Dec. 28, 2021

(51) Int. Cl. H01L 29/786; H01L 27/092; H01L 29/06; H01L 29/423; H01L 21/02; H01L 29/66

(52) U.S. Cl. CPC H01L 29/78696; H01L 21/0259; H01L 27/092; H01L 29/0665; H01L 29/42392; H01L 29/66545; H01L 29/66553; H01L 29/66742; H01L 29/78618

(57) ABSTRACT

A field effect device is provided. The field effect device includes a stack of nano-channels on a substrate, wherein each of the nano channels has a first height, a first width, and a first length, and a vertical nanosheet perpendicular to a major plane of the substrate on opposite sides of the stack of nano-channels, wherein each of the vertical nanosheets has a second height, a second width, and a second length, wherein the second height of the vertical nanosheets is greater than the first width of the nano-channels. The field effect device further includes a gate dielectric layer wrapped around at least a portion of each of the nano-channels and the vertical nanosheets, and a conductive gate fill on the gate dielectric layer.

### BACKGROUND

The present invention generally relates to stacked gate-all-around (GAA) device structures, and more particularly to vertically and horizontally stacked nanosheet (NS) GAA device structures.

A Field Effect Transistor (FET) typically has a source, a channel, and a drain, where current flows from the source to the drain, and a gate that controls the flow of current through the device channel. Field Effect Transistors (FETs) can have a variety of different structures, for example, FETs have been fabricated with the source, channel, and drain formed in the substrate material itself, where the current flows horizontally (i.e., in the plane of the substrate), and FinFETs have been formed with the channel extending outward from the substrate, but where the current also flows from a source to a drain. Depending on the doping of the source and drain, an n-FET or a p-FET can be formed. Two FETs also can be coupled to form a complementary metal oxide semiconductor (CMOS) device, where a p-channel MOSFET and n-channel MOSFET are coupled together.

### SUMMARY

In accordance with an embodiment of the present invention, a field effect device is provided. The field effect device includes a stack of nano-channels on a substrate, wherein each of the nano channels has a first height, a first width, and a first length, and a vertical nanosheet perpendicular to a major plane of the substrate on opposite sides of the stack of nano-channels, wherein each of the vertical nanosheets has a second height, a second width, and a second length, wherein the second height of the vertical nanosheets is greater than the first width of the nano-channels. The field effect device further includes a gate dielectric layer wrapped around at least a portion of each of the nano-channels and the vertical nanosheets, and a conductive gate fill on the gate dielectric layer.

In accordance with another embodiment of the present invention, a complimentary field effect device is provided. The complimentary field effect device includes a first stack of first nano-channels on a substrate, wherein each of the first nano-channels has a first height, a first width, and a first length, and a first vertical nanosheet perpendicular to a major plane of the substrate on opposite sides of the first stack of nano-channels, wherein each of the vertical nanosheets has a second height, a second width, and a second length, wherein the second height of the vertical nanosheets is greater than the first width of the nano-channels. The complimentary field effect device further includes a first gate dielectric layer wrapped around at least a portion of each of the first nano-channels and the first vertical nanosheets, and a first conductive gate fill on the first gate dielectric layer. The complimentary field effect device further includes a second stack of second nano-channels on the substrate, wherein each of the second nano channels has a third height, a third width, and a third length, and a second vertical nanosheet perpendicular to a major plane of the substrate on opposite sides of the second stack of nano-channels, wherein each of the second vertical nanosheets has a fourth height, a fourth width, and a fourth length, wherein the third width of the second nano-channels is greater than the fourth height of the second vertical nanosheets. The complimentary field effect device further includes a second gate dielectric layer wrapped around at least a portion of each of the second nano-channels and the second vertical nanosheets, and a second conductive gate fill on the second gate dielectric layer.

In accordance with yet another embodiment of the present invention, a method of forming a field effect device is provided. The method includes forming one or more stacks of alternating nano-channels and sacrificial sections on a substrate, and epitaxially growing a sacrificial structure on the alternating nano-channels and sacrificial sections, wherein the sacrificial structure is the same material as the sacrificial sections. The method further includes epitaxially growing a vertical nanosheet on each side of the sacrificial structure; and removing the sacrificial structure to leave a stack of nano-channels on the substrate and a vertical nanosheet on opposite sides of the stack of nano-channels.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 illustrates perpendicular cross-sectional side views showing a stack of alternating nanosheet channel layers and sacrificial layers on a bottom sacrificial layer and a substrate, in accordance with an embodiment of the present invention;

FIG. 2 illustrates perpendicular cross-sectional side views showing a stack template formed on alternating nanosheet channel sections and sacrificial sections on a bottom sacrificial section and the substrate, in accordance with an embodiment of the present invention;

FIG. 3 illustrates perpendicular cross-sectional side views showing formation of a fill layer, lateral epitaxial growth of sacrificial material to form a sacrificial structure, and lateral epitaxial growth of a vertical nanosheet on the sacrificial structure, in accordance with an embodiment of the present invention;

FIG. 4 illustrates perpendicular cross-sectional side views showing removal of the stack template from the sacrificial structure, in accordance with an embodiment of the present invention;

FIG. 5 illustrates perpendicular cross-sectional side views showing a dummy gate fill and dummy gate cap formed on the sacrificial structures and vertical nanosheets, and formation of dummy gate sidewalls on the dummy gate fill and dummy gate cap, in accordance with an embodiment of the present invention;

FIG. 6 illustrates perpendicular cross-sectional side views showing removal of portions of the sacrificial structure, vertical nanosheets, and nanosheet channel sections, in accordance with an embodiment of the present invention;

FIG. 7 illustrates perpendicular cross-sectional side views showing recessing of the sacrificial structure between the nanosheet channel sections, in accordance with an embodiment of the present invention;

FIG. 8 illustrates perpendicular cross-sectional side views showing formation of an inner spacer layer on the recessed sacrificial structures and nanosheet channel sections, in accordance with an embodiment of the present invention;

FIG. 9 illustrates perpendicular cross-sectional side views showing removal of portions of the inner spacer layer to form inner spacers on the recessed sacrificial structures and nanosheet channel sections, in accordance with an embodiment of the present invention;

FIG. 10 illustrates perpendicular cross-sectional side views showing formation of source/drains on opposite sides of the vertical nanosheets, nanosheet channel sections, and recessed sacrificial structures, in accordance with an embodiment of the present invention;

FIG. 11 illustrates perpendicular cross-sectional side views showing formation of an interlayer dielectric (ILD) layer on the source/drains and dummy gate sidewalls, and removal of the dummy gate cap, in accordance with an embodiment of the present invention;

FIG. 12 illustrates perpendicular cross-sectional side views showing removal of the dummy gate fill and bottom sacrificial layer and recessing of the fill layer to form gaps between the vertical nanosheets, nanosheet channel sections, and the substrate, in accordance with an embodiment of the present invention;

FIG. 13 illustrates perpendicular cross-sectional side views showing formation of an active gate structure on the vertical nanosheets and nanosheet channel sections, in accordance with an embodiment of the present invention; and

FIG. 14 illustrates cross-sectional side views of a pFET with narrow nanosheets and an nFET with wide nanosheets on two different regions of a substrate, in accordance with an embodiment of the present invention.

### DETAILED DESCRIPTION

Embodiments of the present invention relate to a vertically and horizontally stacked gate-all-around (GAA) nanosheet (NS) device including a vertical nanosheet and a channel stack with perpendicular current flow. The current flow in the device(s) can be horizontal (parallel to the major plane of the substrate) from a source to a drain.

In various embodiments, the vertical nanosheets can have a vertical {110} plane that is parallel to the flow of current within the channel, where the channel can be aligned perpendicularly to the substrate. In various embodiments, a channel with a {001} plane and a substrate with a {001} plane can be used to form an n-type field effect transistor (nFET) device. In various embodiments, a channel with a {110} plane and a substrate with a {001} plane can be used to form an p-type field effect transistor (pFET) device. An Si{110} plane can be used for a pFET device, since hole mobility is high on that plane, and an Si{100} plane can be used for an nFET device since electron mobility is high on that plane.

Exemplary applications/uses to which the present invention can be applied include, but are not limited to: high performance logic devices (e.g., NAND gates, NOR gates, etc.).

It is to be understood that aspects of the present invention will be described in terms of a given illustrative architecture; however, other architectures, structures, substrate materials and process features and steps can be varied within the scope of aspects of the present invention.

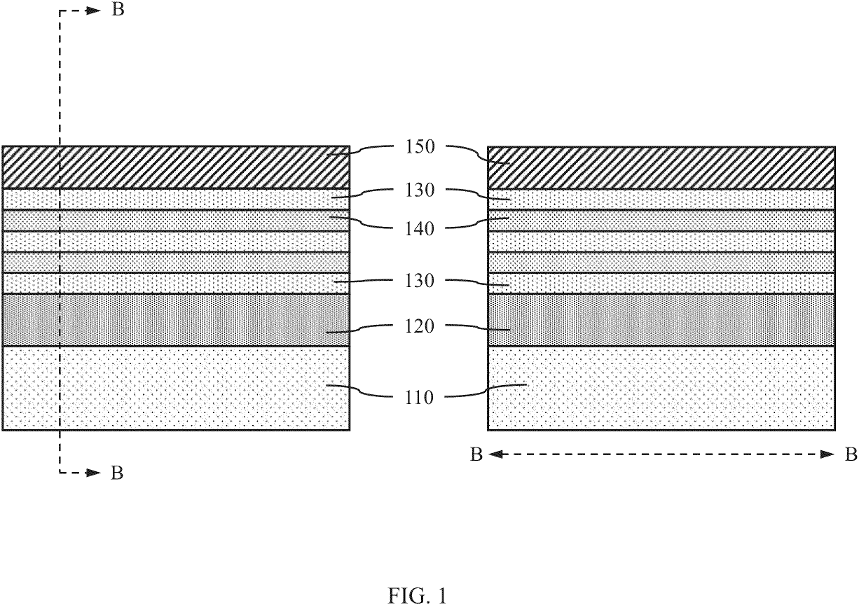

Referring now to the drawings in which like numerals represent the same or similar elements and initially to FIG. 1, FIG. 1 illustrates perpendicular cross-sectional side views showing a stack of alternating nanosheet channel layers and sacrificial layers on a bottom sacrificial layer and a substrate, in accordance with an embodiment of the present invention.

In one or more embodiments, a bottom sacrificial layer 120 can be formed on a substrate, where the bottom sacrificial layer 120 can be formed by an epitaxial growth process on the top surface of the substrate. In various embodiments, the bottom sacrificial layer 120 can be a semiconductor layer grown on the top surface of the substrate 110, where the bottom sacrificial layer 120 can be, for example, silicon-germanium (SiGe) with a germanium concentration in a range of about 15 atomic percent (at.%) to about 75 at.%, or about 60 at.%.

In various embodiments, the substrate 110 can be a semiconductor substrate, where the substrate 110 can be a type IV semiconductor, for example, silicon (Si) or germanium (Ge), or a type IV-IV compound semiconductor, for example, silicon-germanium (SiGe) or silicon carbide (SiC), a type III-V compound semiconductor, for example, gallium arsenide (GaAs), gallium nitride (GaN), or indium phosphide (InP). The substrate material can be a single crystal semiconductor suitable for epitaxial growth of the bottom sacrificial layer 120 and stack of alternating nanosheet channel layers 130 and sacrificial layers 140 on the substrate 110 and bottom sacrificial layers 120.

In one or more embodiments, the nanosheet channel layers 130 can be, for example, silicon (Si) nanosheet layers formed on the bottom sacrificial layer 120 and substrate 110 by epitaxial growth. In various embodiments, the nanosheet channel layers 130 can be nanowires or nanoellipses (referred to collectively as nano-channels); however, nanosheet is used for consistency to refer to each of the nano-forms.

In various embodiment the nanosheet channel layers 130 can have a thickness in a range of about 3 nanometers (nm) to about 15 nm, or about 4 nm to about 9 nm, although other thicknesses are also contemplated.

In one or more embodiments, the sacrificial layers 140 can be, for example, silicon-germanium (SiGe) nanosheet layers formed on the nanosheet channel layers 130 by epitaxial growth to form the alternating stack of nanosheet channel layers 130 and sacrificial layers 140.

In various embodiments, the sacrificial layers 140 can have a thickness in a range of about 6 nanometers (nm) to about 20 nm, or about 8 nm to about 15 nm, although other thicknesses are also contemplated.

In various embodiments, the sacrificial layers 140 can be silicon-germanium (SiGe) with about a germanium concentration of about 15 atomic percent (at.%) to about 35 atomic percent (at.%), or about 25 atomic percent (at.%).

In one or more embodiments, a stack template layer 150 can be formed on the top most layer, where the stack template layer 150 can be formed by a blanket deposition, for example, chemical vapor deposition (CVD), plasma enhanced CVD (PECVD), physical vapor deposition (PVD), and combinations thereof.

In various embodiments, the stack template layer 150 can be a dielectric hardmask material, including, but not limited to, silicon oxide (SiO), silicon nitride (SiN), silicon oxynitride (SiON), silicon boronitride (SiBN), titanium nitride (TiN), and combinations thereof. The stack template layer 150 can be patterned by lithography and etching.

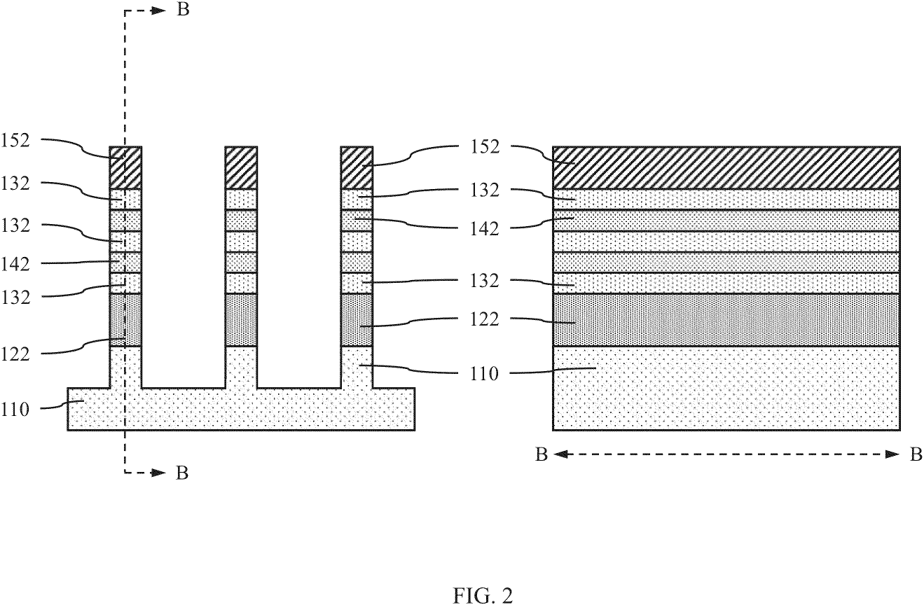

FIG. 2 illustrates perpendicular cross-sectional side views showing a plurality of stack templates formed on alternating nanosheet channel sections and sacrificial sections on a bottom sacrificial section and the substrate, in accordance with an embodiment of the present invention.

In one or more embodiments, the stack template layer 150 can be patterned by lithographic processes and etching to form one or more stack templates 152 on the stack of alternating nanosheet channel layers 130 and sacrificial layers 140.

In one or more embodiments, portions of the nanosheet channel layers 130 and sacrificial layers 140 can be removed, for example, by selective directional etching (e.g., reactive ion etching (RIE)) to form one or more stacks of alternating nanosheet channel sections 132 and sacrificial sections 142 on a bottom sacrificial section 122. In various embodiments, a portion of the substrate 110 beneath the bottom sacrificial layer 120 can also be removed.

In various embodiments, the nanosheet channel sections 132, sacrificial sections 142, and bottom sacrificial section 122 can each have a width in a range of about 5 nm to about 100 nm, or about 10 nm to about 50 nm, or about 15 nm to about 30 nm, although other widths are also contemplated. In various embodiments, a nanowire channel section can have a width in a range of about 5 nm to about 10 nm, or about 7 nm, although other widths are also contemplated. nanosheets and nanowires can be referred to as nano-channels.

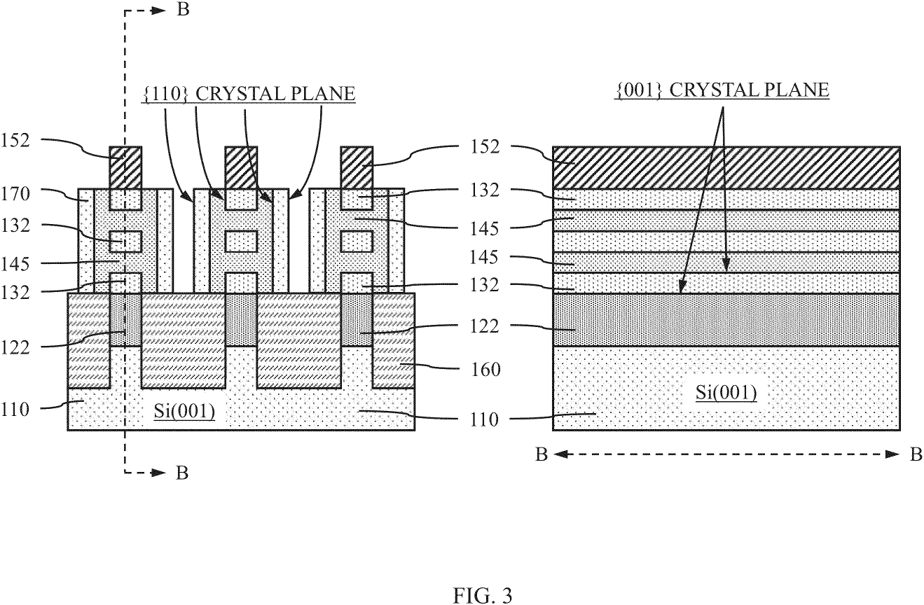

FIG. 3 illustrates perpendicular cross-sectional side views showing formation of a fill layer, lateral epitaxial growth of sacrificial material to form a sacrificial structure, and lateral epitaxial growth of a vertical nanosheet on the sacrificial structure, in accordance with an embodiment of the present invention.

In one or more embodiments, a fill layer 160 can be formed on the substrate 110, where the fill layer 160 can fill in the space between each adjacent pair of the stack of nanosheet channel sections 132 and sacrificial sections 142 on the bottom sacrificial section 122. The fill layer 160 can cover the sidewalls of the bottom sacrificial section 122, where the top surface of the fill layer 160 can be approximately (i.e., within the tolerances of the processes used) coplanar with the interface between the top surface of the bottom sacrificial section 122 and the bottom surface of the bottom most nanosheet channel section 132. In various embodiments, the top surface of the fill layer 160 can be at or below the top surface of the bottom sacrificial section 122.

In various embodiments, the fill layer 160 can be an electrically insulating dielectric material, including, but not limited to, silicon oxide (SiO), silicon nitride (SiN), silicon oxynitride (SiON) silicon oxy carbide (SiOC), silicon oxy carbonitride (SiOCN), silicon boro carbonitride (SiBCN), and combinations thereof.

In one or more embodiments, a sacrificial structure 145 can be formed on the alternating nanosheet channel sections 132 and sacrificial sections 142, where the sacrificial structure 145 can be formed by epitaxially growing a sacrificial material on the exposed sidewall surfaces of the nanosheet channel sections 132 and sacrificial sections 142. In various embodiments, the sacrificial structure 145 can be the same material as the sacrificial sections 142, so the sacrificial structure 145 can be removed with a single selective etch. In various embodiments, the sacrificial structure 145 can be, for example, a layer of silicon-germanium (SiGe) having about the same germanium concentration as the sacrificial sections 142, so the sacrificial structure 145 can be removed with a single selective etch. In various embodiments, the sacrificial structure 145 can have a cross-sectional H-shape or ladder-like shape with the sacrificial sections 142 forming the rungs and the epitaxially grown portion forming the legs.

In one or more embodiments, a vertical nanosheet 170 can be formed on each side of the sacrificial structure 145, where the vertical nanosheet 170 can be formed by lateral epitaxial growth from the exposed sidewalls of the sacrificial structure(s) 145. In various embodiments, the vertical nanosheets 170 can be, for example, a layer of silicon (Si) grown on the sacrificial structures 145, where the vertical nanosheets 170 and nanosheet channel sections 132 can remain after selectively removing the sacrificial structure(s) 145. A gap can be between facing sidewalls of the adjacent vertical nanosheets 170.

In various embodiments, the vertical nanosheet 170 can have a crystal structure from the epitaxial growth such that the vertical nanosheet(s) 170 have a {110} crystal plane vertically along the long axis of the vertical nanosheet 170 when the substrate 110 is a Si(001) substrate, where the {110} crystal plane can be parallel to the flow of current.

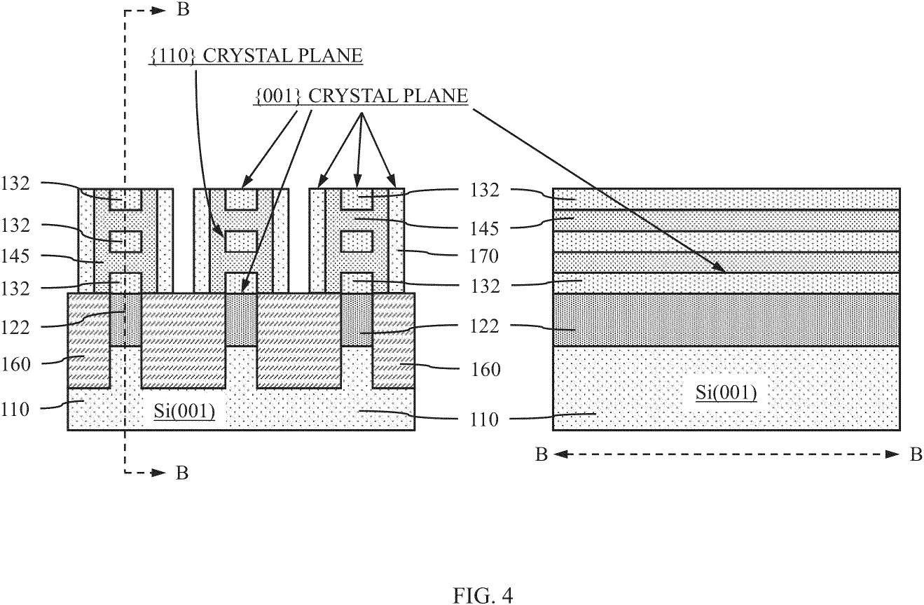

FIG. 4 illustrates perpendicular cross-sectional side views showing removal of the stack template from the sacrificial structure, in accordance with an embodiment of the present invention.

In one or more embodiments, the one or more stack templates 152 can be removed, where the one or more stack templates 152 can be removed using a selective etch. Removal of the one or more stack templates 152 can expose a top surface of a top most nanosheet channel section 132.

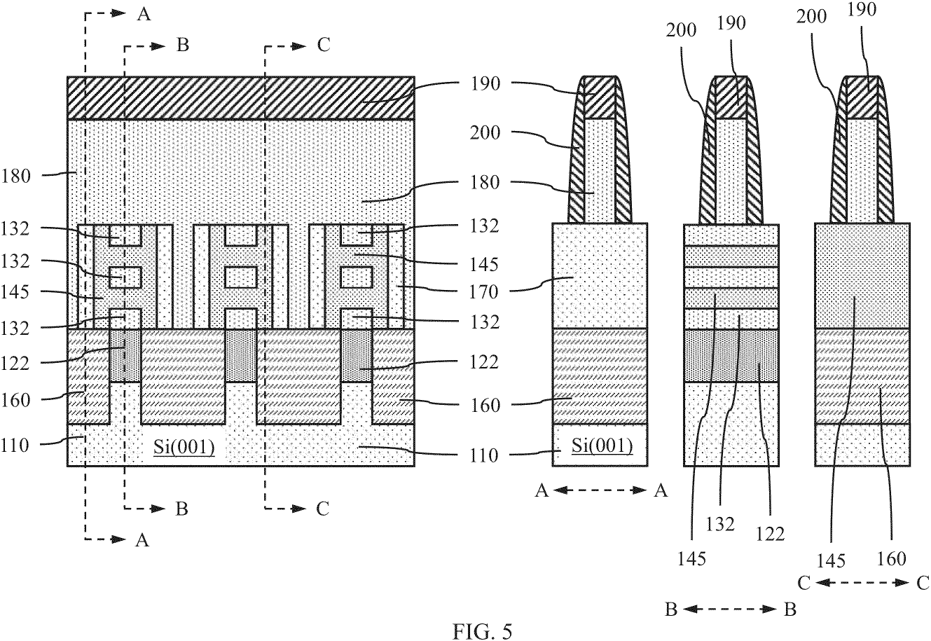

FIG. 5 illustrates perpendicular cross-sectional side views showing a dummy gate fill and dummy gate cap formed on the sacrificial structures and vertical nanosheets, and formation of dummy gate sidewalls on the dummy gate fill and dummy gate cap, in accordance with an embodiment of the present invention.

In one or more embodiments, a dummy gate structure can be formed on the sacrificial structure(s) 145, vertical nanosheets 170, and stack of nanosheet channel sections 132, where the dummy gate structure can include a dummy gate fill 180 and dummy gate cap 190. The dummy gate fill 180 can be formed on the sacrificial structure(s) 145, vertical nanosheets 170, and stack of nanosheet channel sections 132 by a blanket deposition (e.g., CVD, PECVD, PVD). The dummy gate cap 190 can be formed on the dummy gate fill 180 and used to pattern the dummy gate fill 180 to form the dummy gate structures. The dummy gate fill 180 can fill in the gaps between the vertical nanosheets 170 and extend over the stack of nanosheet channel sections 132. The dummy gate fill 180 can be a selectively removable material, including, but not limited to, amorphous silicon (a-Si), amorphous germanium (a-Ge), amorphous carbon (a-C), and combinations thereof.

In one or more embodiments, dummy gate sidewalls 200 can be formed on the dummy gate fill 180 and dummy gate cap 190, where the dummy gate sidewalls 200 can be formed by depositing a gate sidewall layer and removing portions of the sidewall layer from horizontal surfaces using a selective, directional etch.

In various embodiments, the gate sidewall layer and dummy gate sidewalls 200 can be an electrically insulating dielectric material, including, but not limited to, silicon oxide (SiO), silicon nitride (SiN), silicon oxynitride (SiON) silicon oxy carbide (SiOC), silicon oxy carbonitride (SiOCN), silicon boro carbonitride (SiBCN), and combinations thereof.

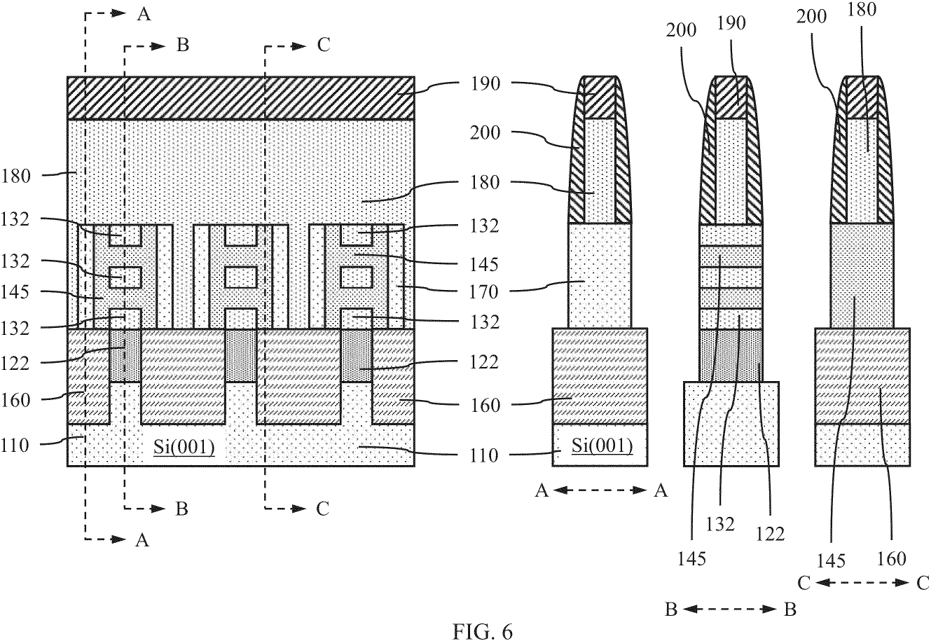

FIG. 6 illustrates perpendicular cross-sectional side views showing removal of portions of the sacrificial structure, vertical nanosheets, and nanosheet channel sections, in accordance with an embodiment of the present invention.

In one or more embodiments, portions of the sacrificial structure 145, vertical nanosheets 170, and nanosheet channel sections 132 extending laterally out beyond the dummy gate sidewalls 200 can be removed using one or more selective directional etching (e.g., RIE), where etching can stop at the top surface of the fill layer 160. Trimming back the nanosheet channel sections 132, sacrificial sections 145, and bottom sacrificial section 122 can determine the length of the nanosheet channel sections 132 beneath the dummy gate structure and dummy gate sidewalls 200.

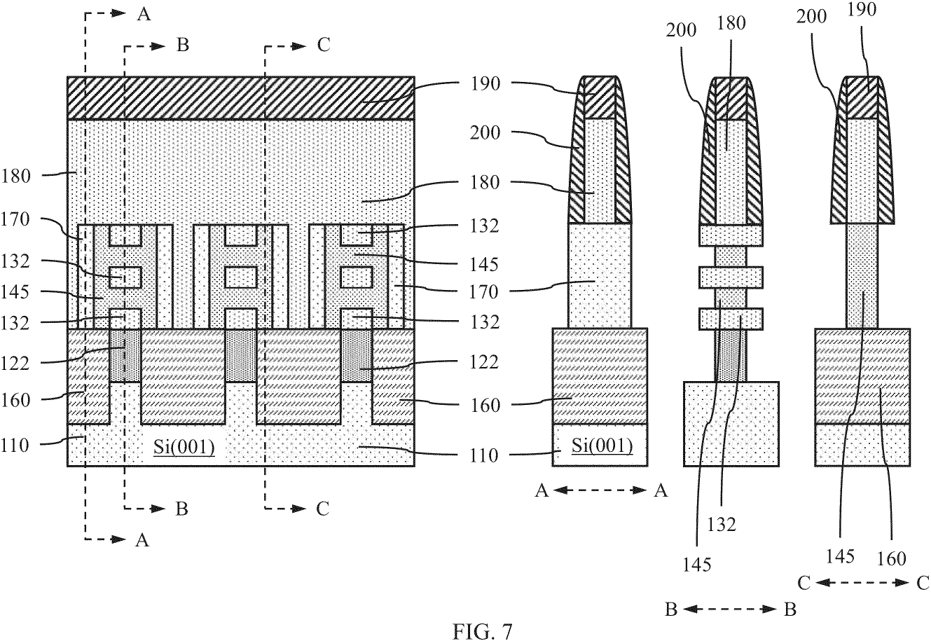

FIG. 7 illustrates perpendicular cross-sectional side views showing recessing of the sacrificial structure between the nanosheet channel sections, in accordance with an embodiment of the present invention.

In one or more embodiments, the sacrificial structure(s) 145 and the bottom sacrificial section(s) 122 can be recessed to form inner spacer cavities between the nanosheet channel sections 132, where the sacrificial structure 145 and the bottom sacrificial section 122 can be recessed using a selective isotropic etch, for example, a wet chemical etch or dry plasma etch. In various embodiments, the recessed sacrificial structure 145 and the bottom sacrificial section 122 can have approximately the same width as the dummy gate fill 180 and dummy gate cap 190.

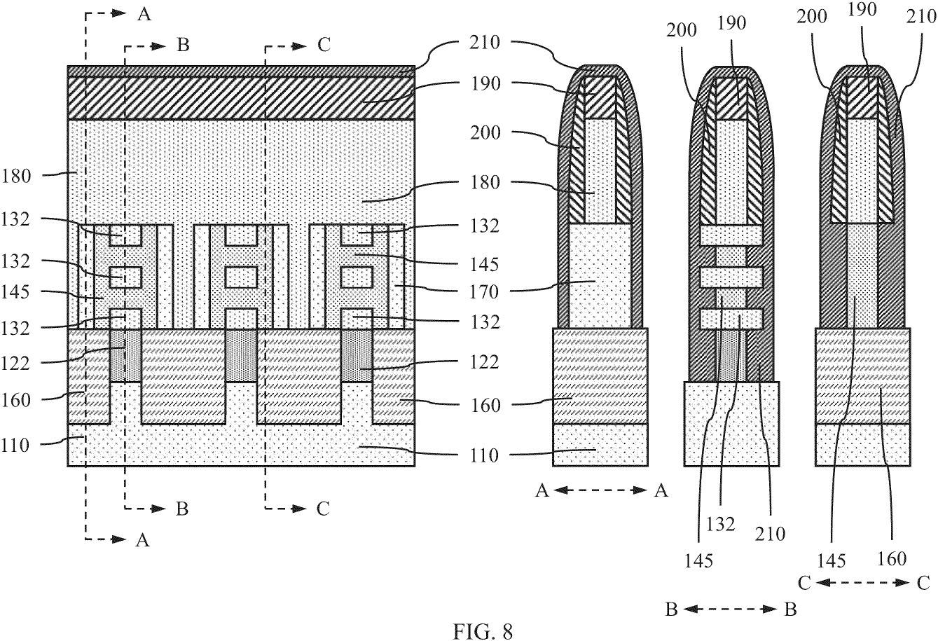

FIG. 8 illustrates perpendicular cross-sectional side views showing formation of an inner spacer layer on the recessed sacrificial structures and nanosheet channel sections, in accordance with an embodiment of the present invention.

In one or more embodiments, an inner spacer layer 210 can be formed on the recessed sacrificial structures 145, bottom sacrificial section 122, and nanosheet channel sections 132, where the inner spacer layer 210 can be formed by a conformal deposition (e.g., ALD, PEALD). Portions of the inner spacer layer 210 can be removed using a selective isotropic etch (e.g., Plasma etch). The inner spacer layer 210 can cover portions of the vertical nanosheets 170 and nanosheet channel sections 132, where the inner spacer layer 210 is sufficiently thick to fill in the inner spacer cavities.

In various embodiments, the inner spacer layer 210 can be an electrically insulating dielectric material, including, but not limited to, silicon oxide (SiO), silicon nitride (SiN), silicon oxynitride (SiON) silicon oxy carbide (SiOC), silicon oxy carbonitride (SiOCN), silicon boro carbonitride (SiBCN), and combinations thereof.

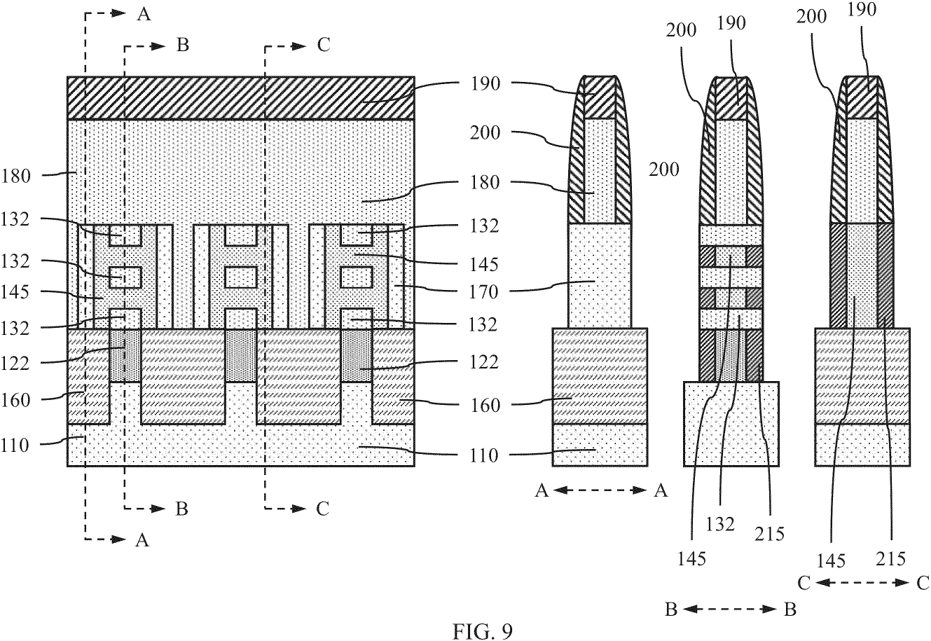

FIG. 9 illustrates perpendicular cross-sectional side views showing removal of portions of the inner spacer layer to form inner spacers on the recessed sacrificial structures and nanosheet channel sections, in accordance with an embodiment of the present invention.

In one or more embodiments, the portions of the inner spacer layer 210 extending outside of the inner spacer cavities can be removed to for inner spacers 215 between the nanosheet channel sections 132 and vertical nanosheets 170, where the portions of the inner spacer layer 210 can be removed using a selective directional etch and/or a selective isotropic etch.

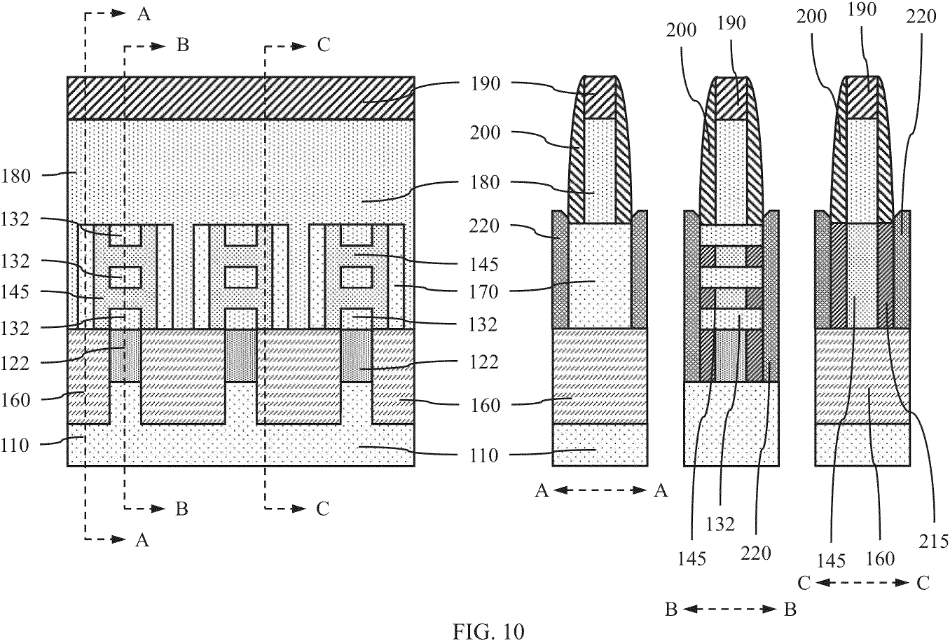

FIG. 10 illustrates perpendicular cross-sectional side views showing formation of source/drains on opposite sides of the vertical nanosheets, nanosheet channel sections, and recessed sacrificial structures, in accordance with an embodiment of the present invention.

In one or more embodiments, source/drains 220 can be formed on opposite sides of the vertical nanosheets 170, nanosheet channel sections 132, and recessed sacrificial structures 145, where the source/drains 220 can be formed by lateral epitaxial growth on the exposed semiconductor surfaces of the vertical nanosheets 170 and nanosheet channel sections 132. The source/drains 220 can extend laterally along the inner spacers 215 and sacrificial structure 145.

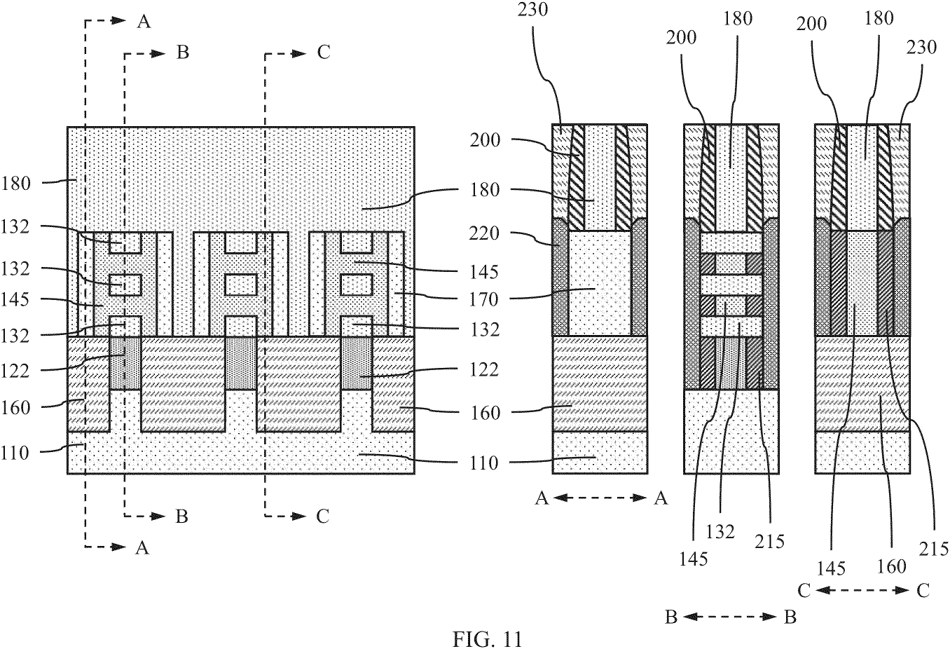

FIG. 11 illustrates perpendicular cross-sectional side views showing formation of an interlayer dielectric (ILD) layer on the source/drains and dummy gate sidewalls, and removal of the dummy gate cap, in accordance with an embodiment of the present invention.

In one or more embodiments, an interlayer dielectric (ILD) layer 230 can be formed on the source/drains 220 and dummy gate sidewalls 200, where the interlayer dielectric (ILD) layer 230 can be formed by a conformal deposition (e.g., ALD, PEALD), a blanket deposition (e.g., CVD, PECVD), or a combination thereof.

In various embodiments, the interlayer dielectric (ILD) layer 230 can be an electrically insulating dielectric material, including, but not limited to, silicon oxide (SiO), silicon nitride (SiN), silicon oxynitride (SiON) silicon oxy carbide (SiOC), silicon oxy carbonitride (SiOCN), silicon boro carbonitride (SiBCN), and combinations thereof.

In one or more embodiments, the dummy gate cap(s) 190 can be removed using chemical-mechanical polishing (CMP) and/or a selective etch to expose the underlying dummy gate fill 180. The CMP can also remove an upper portion of the interlayer dielectric (ILD) layer 230 to provide a uniform surface.

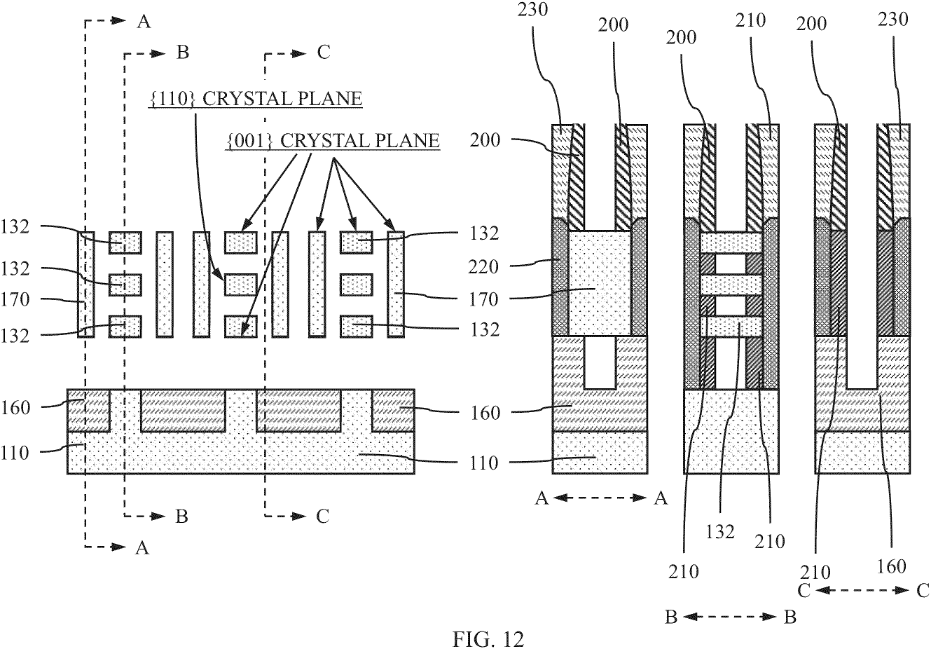

FIG. 12 illustrates perpendicular cross-sectional side views showing removal of the dummy gate fill and bottom sacrificial layer and recessing of the fill layer to form gaps between the vertical nanosheets, nanosheet channel sections, and the substrate, in accordance with an embodiment of the present invention.

In one or more embodiments, the dummy gate fill 180 can be removed using a selective isotropic etch to expose the underlying vertical nanosheets 170, nanosheet channel sections 132, and recessed sacrificial structures 145.

In one or more embodiments, the sacrificial structures 145 can be removed using a selective isotropic etch to expose the underlying vertical nanosheets 170 and nanosheet channel sections 132.

In various embodiments, a portion of the fill layer 160 beneath the vertical nanosheets 170 and sacrificial structures 145 can be selectively removed. This is for exposing a bottom surface of vertical nanosheets 170 and sidewall(s) of the sacrificial section(s) 122 by recessing the fill layer 160 using a selective isotropic etch, for example, a wet chemical etch or dry plasma etch. In various embodiments, the amount removed by etching can be about the thickness of the vertical nanosheets (e.g., < 10 nm) especially when the top surface of the fill layer 160 is below the top surface of the bottom sacrificial section 122 because the bottom sacrificial section 122 would not need to be exposed by recessing the fill layer 160. The sidewall of sacrificial section 122 may not be exposed, so that it can be selectively removed along with sacrificial structures 145.

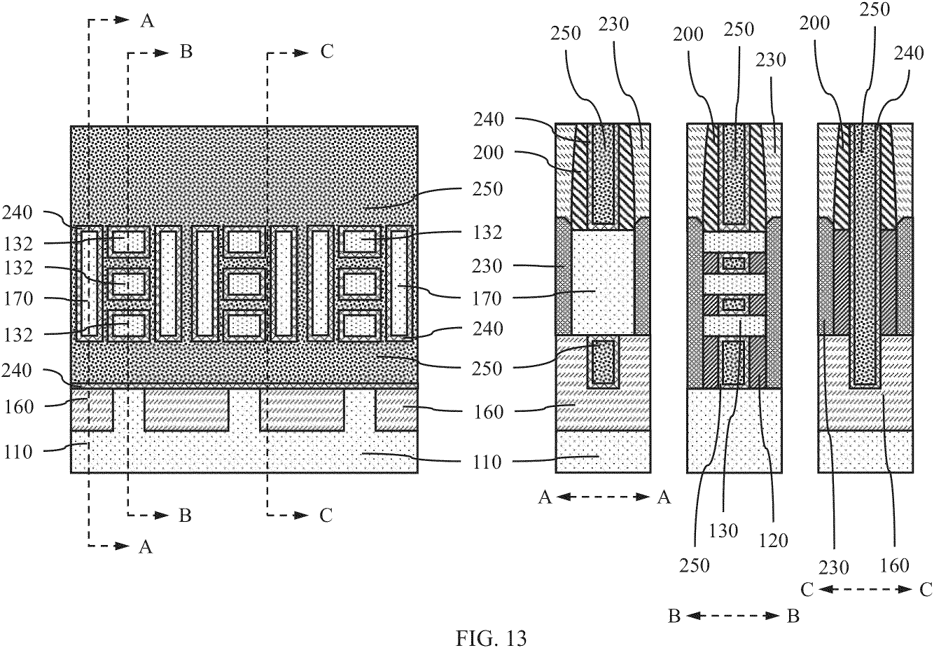

FIG. 13 illustrates perpendicular cross-sectional side views showing formation of an active gate structure on the vertical nanosheets and nanosheet channel sections, in accordance with an embodiment of the present invention.

In one or more embodiments, an active gate structure can be formed on the vertical nanosheets 170 and nanosheet channel sections 132, where the active gate structure can include a gate dielectric layer 240 formed on the exposed surfaces of the vertical nanosheets 170 and nanosheet channel sections 132, and a conductive gate fill 250 formed on the gate dielectric layer 240. The gate dielectric layer 240 can be formed by a conformal deposition of an electrically insulating dielectric material on the exposed surfaces of the vertical nanosheets 170 and nanosheet channel sections 132. The conductive gate fill 250 can be formed by a conformal deposition of a conductive material on the gate dielectric layer 240.

In various embodiments, the gate dielectric layer 240 can be an electrically insulating dielectric material, including, but not limited to, silicon oxide, a high-k dielectric material, or a combination thereof. In various embodiments, the high-k dielectric material can include, but not be limited to, hafnium oxide (HfO), zirconium oxide (ZrO), hafnium-zirconium oxide (HfZr)), tantalum oxide (TaO), and combinations thereof.

In various embodiments, the conductive gate fill 250 can be a metal, including, but not limited to, copper (Cu), tungsten (W), ruthenium (Ru), cobalt (Co), molybdenum (Mo), a conductive metal compound, including, but not limited to, tantalum nitride (TaN), titanium nitride (TiN), tantalum carbide (TaC), titanium carbide (TiC), and combinations thereof. The conductive gate fill 250 can be a multilayer of a work function material and a metal.

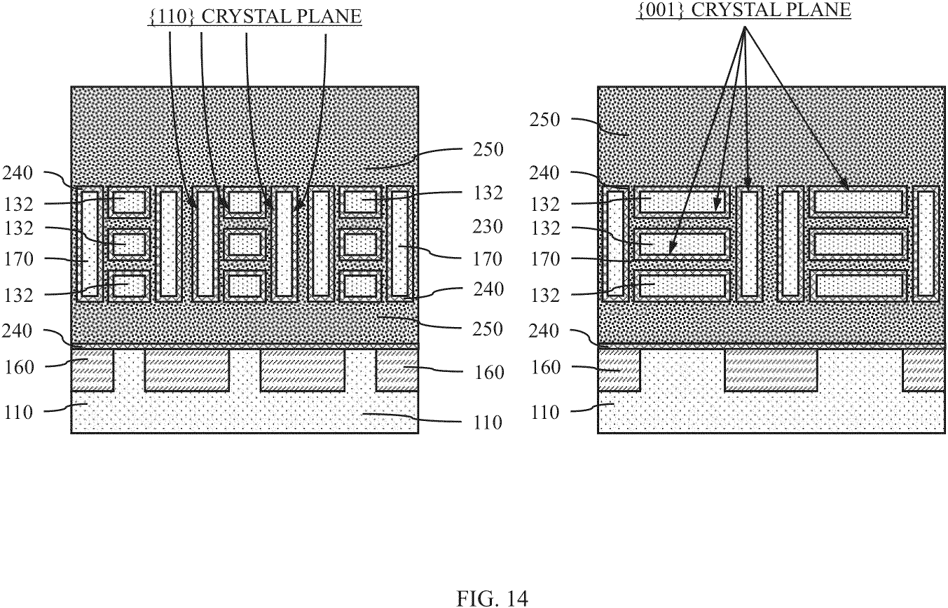

FIG. 14 illustrates cross-sectional side views of a pFET with narrow nanosheets and an nFET with wide nanosheets on two different regions of a substrate, in accordance with an embodiment of the present invention.

In one or more embodiments, an n-type field effect transistor (nFET) device having wider nanosheets parallel with the plane of the substrate can be formed on a first region of the substrate, and a p-type field effect transistor (pFET) device can be formed on a second region of the substrate, where the first region and second region can be adjacent to form complimentary field effect transistor (CFET) devices. The pFETs can have device channels with a greater amount of {110} surface area, and the nFETs can have device channels with a greater amount of {001} surface area to increase charge carrier mobility. The methods described herein can be used to form FETs having nanosheets with different widths based on masking and lithography to define the width and length of the stack templates for forming the stack template(s) and alternating nanosheet channel sections and sacrificial sections on a bottom sacrificial section and the substrate.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element’s or feature’s relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Having described preferred embodiments of devices and method of fabricating the devices (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A field effect device, comprising:
a stack of nano-channels on a substrate, wherein each of the nano-channels has a first height, a first width, and a first length;
a vertical nanosheet perpendicular to a major plane of the substrate on opposite sides of the stack of nano-channels, wherein each of the vertical nanosheets has a second height, a second width, and a second length, wherein the second height of the vertical nanosheets is greater than the first width of the nano-channels;
a gate dielectric layer wrapped around at least a portion of each of the nano-channels and the vertical nanosheets; and
a conductive gate fill on the gate dielectric layer.

2. The field effect device of claim 1, further comprising a source/drain on each of opposite sides of the nano-channels and the vertical nanosheets.

3. The field effect device of claim 2, wherein the source/drains are doped with a p-type dopant to form a p-type field effect transistor device.

4. The field effect device of claim 3, wherein the substrate, the nano-channels and the vertical nanosheets are silicon (Si).

5. The field effect device of claim 4, wherein surfaces of the vertical nanosheet formed by the second height and second length is a {110} crystal plane, and the substrate surface is a {001} crystal plane.

6. The field effect device of claim 5, further comprising a fill layer beneath at least a portion of the vertical nanosheets.

7. The field effect device of claim 6, further comprising inner spacers between the nano-channels.

8. A complimentary field effect device, comprising:
a first stack of first nano-channels on a substrate, wherein each of the first nano channels has a first height, a first width, and a first length;
a first vertical nanosheet perpendicular to a major plane of the substrate on opposite sides of the first stack of nano-channels, wherein each of the vertical nanosheets has a second height, a second width, and a second length, wherein the second height of the vertical nanosheets is greater than the first width of the nano-channels;
a first gate dielectric layer wrapped around at least a portion of each of the first nano-channels and the first vertical nanosheets;
a first conductive gate fill on the first gate dielectric layer;
a second stack of second nano-channels on the substrate, wherein each of the second nano channels has a third height, a third width, and a third length;
a second vertical nanosheet perpendicular to a major plane of the substrate on opposite sides of the second stack of nano-channels, wherein each of the second vertical nanosheets has a fourth height, a fourth width, and a fourth length, wherein the third width of the second nano-channels is greater than the fourth height of the second vertical nanosheets;
a second gate dielectric layer wrapped around at least a portion of each of the second nano-channels and the second vertical nanosheets;
a second conductive gate fill on the second gate dielectric layer.

9. The complimentary field effect device of claim 8, further comprising a first source/drain on each of opposite sides of the first nano-channels and the first vertical nanosheets, and a second source/drain on each of opposite sides of the second nano-channels and the second vertical nanosheets.

10. The complimentary field effect device of claim 9, wherein the first source/drains are doped with a p-type dopant to form a p-type field effect transistor device.

11. The complimentary field effect device of claim 10, wherein surfaces of the first vertical nanosheets formed by the second height and second length are a {110} crystal plane, and the substrate surface is a {001} crystal plane.

12. The complimentary field effect device of claim 11, wherein the second source/drains are doped with an n-type dopant to form an n-type field effect transistor device.

13. The complimentary field effect device of claim 12, wherein surfaces of the second nano-channels formed by the third width and third length are a {001} crystal plane, and the substrate surface is a {001} crystal plane.

14. A method of forming a field effect device, comprising:
forming one or more stacks of alternating nano-channels and sacrificial sections on a substrate;
epitaxially growing a sacrificial structure on the alternating nano-channels and sacrificial sections, wherein the sacrificial structure is the same material as the sacrificial sections;
epitaxially growing a vertical nanosheet on each side of the sacrificial structure; and removing the sacrificial structure to leave a stack of nano-channels on the substrate and a vertical nanosheet on opposite sides of the stack of nano-channels.

15. The method of claim 14, further comprising forming a source/drain on each of opposite sides of the nano-channels and the vertical nanosheets.

16. The method of claim 15, further comprising removing a bottom sacrificial section beneath the stack of nano-channels.

17. The method of claim 16, further comprising forming a gate dielectric layer wrapped around at least a portion of each of the nano-channels and the vertical nanosheets.

18. The method of claim 17, further comprising forming a conductive gate fill on the gate dielectric layer.

19. The method of claim 18, wherein each of the vertical nanosheets has a height that is greater than the width of the nano-channels, and wherein the source/drains are doped with a p-type dopant to form a p-type field effect transistor device.

20. The method of claim 18, wherein each of the nano-channels has a width that is greater than the height of the vertical nanosheets, and wherein the source/drains are doped with an n-type dopant to form a n-type field effect transistor device.
